(19) United States
(12) Patent Application Publication
(10) Pub. No.: US 2014/0370695 A1
(43) Pub. Date: Dec. 18, 2014

(54) METHOD FOR FABRICATING A SEMICONDUCTOR DEVICE

(71) Applicant: Oleg Kononchuk, Grenoble (FR)

(72) Inventor: Oleg Kononchuk, Grenoble (FR)

(73) Assignee: SOITEC, Bernin (FR)

(21) Appl. No.: 14/362,305

(22) PCT Filed: Dec. 15, 2011
(86) PCT No.: PCT/EP2011/006350

§ 371 Date: Sep. 4, 2014

(30) Foreign Application Priority Data
Dec. 27, 2010 (FR) 10/05133

(51) Int. Cl. H01L 29/872; H01L 21/30; H01L 29/34; H01L 29/20; H01L 21/48; H01L 29/06; H01L 21/302; H01L 29/16

(52) U.S. Cl. CPC H01L 29/872; H01L 21/302; H01L 21/30; H01L 29/16; H01L 29/20; H01L 29/2003; H01L 21/4814; H01L 29/0603; H01L 29/34
USPC 438/571

(57) ABSTRACT

The present invention relates to a method for fabricating a semiconductor structure comprising a semiconductor layer and a metallic layer, to improve the breakdown voltage properties of the device and reduce leakage currents, the method comprises the steps of a) providing a semiconductor layer comprising defects and/or dislocations; b) removing material at one or more locations of the defects and/or dislocations thereby forming pits in the semiconductor layer, c) passivating the pits, and c) providing the metallic layer over the semiconductor layer. The invention also relates to a corresponding semiconductor structure.

### CROSS-REFERENCE TO RELATED APPLICATIONS

This application is a national phase entry under 35 U.S.C. § 371 of International Patent Application PCT/EP2011/006350, filed Dec. 15, 2011, designating the United States of America and published in English as International Patent Publication WO2012/089315 A1 on Jul. 5, 2012, the disclosure of which is hereby incorporated herein in its entirety by this reference.

### TECHNICAL FIELD

The present invention relates to a method for fabricating a semiconductor structure and a semiconductor structure comprising a semiconductor layer and a metallic layer. In particular, the invention relates to a method for fabricating a semiconductor structure and a semiconductor structure for reducing leakage currents, improving the breakdown voltage characteristics and improving the performance of semiconductor devices, in particular, for Schottky barrier used in power semiconductor devices.

### BACKGROUND

Typically, a Schottky diode comprises a metal layer provided over a semiconductor layer. A Schottky barrier is formed at the juncture of the metal and the semiconductor. Schottky diode or Schottky barrier diode are widely used for radio frequency applications as a mixer or detector diode. Schottky diode is also used, for example, in power applications such as switches or rectifiers because of its low forward voltage drop and fast switching when compared to conventional p-n junction diode. Further, Schottky diodes, due to its lower reverse voltage and fast recovery characteristics, find commercial application in such as radiation detectors, imaging devices and wired and wireless communications products. However, one problem with the Schottky diode is that they exhibit, in general, higher leakage currents and lower breakdown voltages.

### BRIEF SUMMARY

Starting therefrom, it is an object of the present invention to provide a method for fabricating a semiconductor device structure and a semiconductor device structure with which leakage currents can be reduced, improved breakdown voltage characteristics can be obtained and an improved device performance can be obtained.

The object of the invention is achieved with a method for fabricating a semiconductor structure comprising a semiconductor layer and a metallic layer, comprises the steps of: a) providing a semiconductor layer comprising defects and/or dislocations; b) removing material at one or more locations of the defects and/or dislocations thereby forming pits in the semiconductor layer, c) passivating the pits, and d) providing the metallic layer over the semiconductor layer.

The inventors found out that the leakage currents and breakdown down voltage observed at the metal-semiconductor interface can be reduced and enhanced, respectively, by removing material in areas of dislocations and/or defects in the semiconductor material without influencing the quality of the metal layer. That is, since the pits have been passivated, the material below the metallic layer and in between the passivated pits would be free from defects and/or dislocations, or would have at least less defects and/or dislocations than that of the bulk of the material, and this give rise to the device having improved performance.

Herein the term “defect” is used to refer to any threading dislocations, loop dislocation, stacking faults and grain boundaries, etc., in the material.

Preferably, the passivating step can include at least partially filling the pits with a dielectric material. By filling the pits with a dielectric material, further leakage currents can be reduced at the metal-semiconductor interface and, thus an improved performance of a power device can be realized. That is, since the pits have been at least partially filled dielectric material, the material below the metallic layer, and in between the dielectric material would be free from defects and/or dislocations or would have at least less defects and/or dislocations than that of the bulk of the material and this gives rise to the device having improved performance.

Preferably, the step of the removing material can comprise a step of etching the surface of the semiconductor layer preferentially at one or more locations of the defects such that one or more pits are formed in the semiconductor layer. Already existing pits at the locations of surface defects can be enlarged at the same time. The pits are preferably sufficiently large so that the disordered material is removed from the surface such that pits intercept defects and/or dislocations present in the interior of the semiconductor layers. Such an etching allows removing selectively or preferentially the regions having the defects and/or dislocations leaving out the non-defective regions.

Preferably, the dielectric material can be chosen from any one of silicon oxide, silicon nitride and mixtures thereof. Such dielectric material improves the electrical property at the interface between the metallic and semiconductor layers for device applications.

Preferably, the dielectric material can completely fill the regions from which the material is removed in step b). By completely filling the etched regions, an essentially defect-free surface layer can be obtained. The filling can be performed by depositing or by otherwise placing dielectric material on the surface of the layer so as to occlude the surface openings of the pits and cover any exposed portions of the walls of the pits, but such that intact portions of the surface of the semiconductor layer away from the pits are exposed.

Preferably, the method can comprise a step of polishing the surface of the semiconductor layer after step c). By doing so, excessive materials deposited on the surface of the semiconductor layer can be removed. After filling the etched regions with the dielectric material, the surface of the semiconductor device structure can be polished such that the surface is an essentially defect and/or dislocation free surface. Preferably, the polishing step can include a surface smoothing step for smoothing the passivated surface of the semiconductor layer.

Advantageously, the semiconductor layer can be chosen from any one of GaN, Silicon, strained Silicon, Germanium, SiGe or a III-V material, III/N material, binary or ternary or quaternary alloy like GaN, InGaN, AlGaN, AlGaInN and the likes. Preferably, the metallic layer can be chosen from any one of Al, Au, Pt, chromium, palladium, tungsten, molybdenum or silicides from the same, polycrystalline or amorphous material and alloys or combinations thereof. These metals provide Schottky barriers with desired electrical properties and have desired adhesion with the chosen materials for the semiconductor layer.

Preferably, the metallic layer is provided by any one of physical vapor deposition (PVD), sputtering and chemical vapor deposition such that the metallic layer has desirable adhesion properties with the underlying semiconductor layer.

The object of the invention is also achieved by a semiconductor structure comprises a semiconductor layer and a metallic layer provided over the semiconductor layer, wherein pits at least partially filled with a dielectric material are present in the semiconductor layer. That is, since the pits have been at least partially filled dielectric material, the material below the metallic layer, and in between the dielectric material would be devoid free from defects and/or dislocations or would have at least less defects and/or dislocations than that of the bulk of the material and this give rise to the device having improved performance.

Advantageously, the metallic layer is provided on the semiconductor layer and the pits extend up to the interface with the metallic layer.

With such a metal-semiconductor interface, breakdown voltage characteristics and leakage currents can be improved and reduced, respectively, in the subsequent devices.

Preferably, the dielectric material can be chosen from any one of silicon oxide, silicon nitride and mixtures thereof. Such dielectric material improves the electrical property at the interface between the metallic and semiconductor layers for device applications.

Preferably, the dielectric material can completely fill the one or more regions. By completely filling the etched regions, an essentially defect-free surface layer is obtained.

According to a preferred embodiment, the pits filled with dielectric material can be arranged on top of dislocations and/or defects in the semiconductor layer. Therefore, a negative impact of the defects and/or dislocations on the breakdown voltage can be prevented. That is, since the pits filled with dielectric material are arranged on top of the defects and/or dislocations, the material below the metallic layer, and in between the dielectric material would be free from defects and/or dislocations or would have at least less defects and/or dislocations than that of the bulk of the material and this give rise to the device having improved performance.

The object of the present invention is also achieved by a device using the semiconductor structure as described above.

### BRIEF DESCRIPTION OF THE DRAWINGS

Specific embodiments of the present invention will become more apparent from the present description with reference to the accompanying drawings, wherein:

FIGS. 1a-1e illustrate a first embodiment of a method for preparing a semiconductor structure with a semiconductor layer and a metallic layer.

FIGS. 1a-1e illustrate a method for fabricating a semiconductor structure according to a first embodiment of the invention.

FIG. 1a illustrates a cross-sectional view of a starting semiconductor structure 1. The semiconductor structure 1 comprises a substrate 3, and a semiconductor layer 5 provided over the substrate 3. Further layers, like buffer layers, etc., may be present between the substrate 3 and the semiconductor layer 5.

The substrate 3 in this embodiment serves as a starting material for the epitaxial growth of the semiconductor layer 5 and is, e.g., a SiC or Sapphire substrate or the like. The semiconductor layer 5 is made of a semiconductor material, preferably of GaN, but could also be of Silicon, strained Silicon, Germanium, SiGe or the such as III-V material, III/N material, binary or ternary or quaternary alloy like GaN, InGaN, AlGaN, AlGaInN and the likes. The semiconductor layer 5 can be provided over the substrate 3, via an epitaxial growth process or can be otherwise provided over the substrate 3, for example, by a layer transfer and the likes. In case of a layer transfer, the semiconductor layer 5 may be detached from a bulk substrate by implantation of ionic species following SMARTCUT® technology and bonded to the substrate 3. The semiconductor layer 5 may also be grown by epitaxy on a seed substrate before transfer.

According to a variant, substrate 3 could also be a substrate comprising transferred layers, like a GaNOS substrate, corresponding to a sapphire substrate with a transferred GaN layer that will be used as a seed layer. This type of substrates could comprise metallic or isolating layers as bonding layer between the transferred layer and the substrate depending on the desired properties, e.g., electric or thermal conductivity, etc. The substrate 3 could also be a template substrate, e.g., a sapphire substrate with a thin GaN layer grown thereon.

In this embodiment, the semiconductor layer 5 is doped with an n or p-type dopant. The semiconductor layer 5 can be doped with low or high dosage of dopants depending on the application.

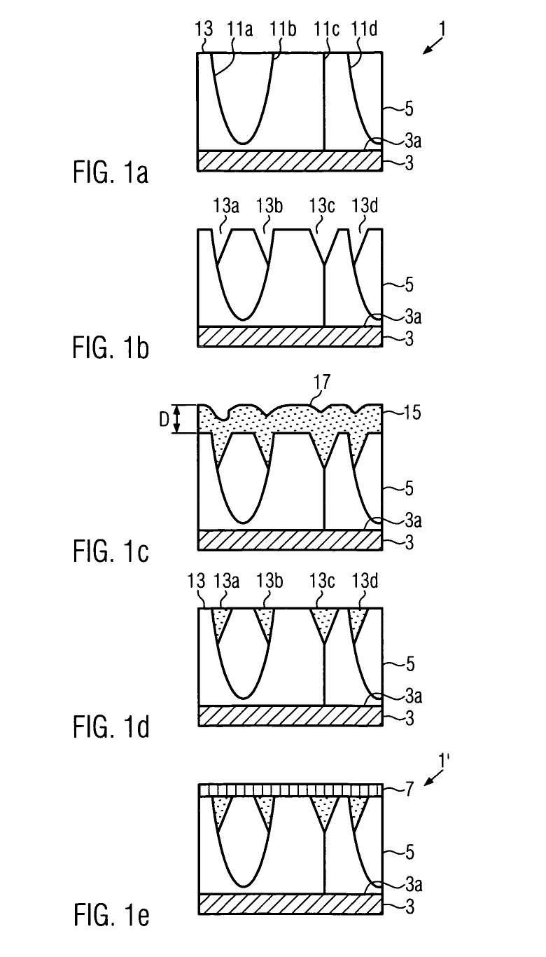

The semiconductor layer 5 as illustrated in FIG. 1 a comprises a plurality of defects and/or dislocations 11a-11c. The defects and/or dislocations 11a-11c in the semiconductor layer 5 can be due to crystal lattice mismatch or different coefficients of thermal expansion with respect to the material of the substrate 3 or the seed substrate.

In an embodiment of the present invention, defects and/or dislocations 11b-11d may arise at a region 3a in the vicinity between the substrate 3 and the semiconductor layer 5, for example, due to crystal and/or physical properties mismatch between the material of the substrate 3 and the material of the semiconductor layer 5 and defect 11a may arise due to loop dislocation.

The defects and/or dislocations 11a-11d may continue and/or propagate along the thickness direction of the semiconductor layer 5 up to the surface of the semiconductor layer 5. The defects and/or dislocations 11a-11d extend typically up to an exposed surface 13 of the semiconductor layer 5. The exposed surface 13 typically has a surface defect and/or dislocation density of up to 1×107 cm-2 for III-N materials such as GaN. For Si or Ge materials or for alloys Sil-yGey, where y>0.2, the defect density is less than 1×106 cm-2. These values depend however strongly on the thickness of the layer 5, as will be explained below.

The invention is of interest below a certain dislocation density which is actually a function of layer thickness. Indeed, depending on the thickness of the layer, the size of the pit formed by etching is more or less important and the entirety of the pits could cover the total surface of the semiconductor, so that one would have to polish the material up to a certain level to find again the semiconductor material.

Typically, when the layer is GaN with 500 nm thickness, the pit after etching has a diameter of about 1 μm. In this case the material should present a dislocation density below 1 e7/cm2, to have GaN material at the surface 13 to prevent unnecessary polishing into the GaN layer. If the layer has a thickness of 100 nm, the pit will have a dimension of 200 nm and the dislocation density could go up to 1 e8/cm2.

The defect density is typically measured by methods known in the art, including, atomic force microscopy, optical microscopy, scanning electron microscopy and transmission electron microscopy. According to the present embodiment, the preferred method for measuring the defect density is by transmission electron microscopy (TEM).

Such defects and/or dislocations 11a-11d hinder the performance of the semiconductor device structure 1, for instance, concerning breakdown voltage, leakage currents and further negatively affects the quality of the exposed surface 13.

FIG. 1b illustrates a step of removing material starting from the exposed surface 13 of the semiconductor layer 5. The material is removed at one or more locations of the defects and/or dislocations 11a-11d. The material can be removed, for example, by a selective or preferential etching using such as HCl for, for example, III-N and silicon materials. Such an etching creates a plurality of etched regions 13a-13d over the exposed surface 13.

According to an embodiment of the invention, the material removal step is carried out at least until the defects and/or dislocations 11a-11d are removed from the vicinity of the exposed surface 13. Thus, the high electric field region is essentially free of defects and/or dislocations. This leads to an improved performance of the semiconductor device, as the breakthrough voltage properties and leakage current characteristics are optimized.

The exposed surface 13 having undergone etching to form the regions 13a-13d will then be passivated for further device fabrication steps. FIG. 1c illustrates a step of filing the regions 13a-13d with a dielectric layer or a dielectric material 15. According to a variant, the filling could be partial.

To fill the pits, a dielectric 15 is deposited on the exposed surface 13 such that the regions 13a-13c are at least partially filled with the dielectric material 15. The filling of dielectric material can be performed by depositing using any one of chemical vapor deposition (CVD), plasma enhanced chemical vapor deposition (PECVD), low-pressure chemical vapor deposition (LPCVD) or by otherwise placing dielectric material on the exposed surface 13 of the semiconductor layer 5 so as to occlude the surface openings of the pits and cover any exposed portions of the walls of the pits. In this embodiment, the dielectric material 15, depending on the application, can be chosen from any one of silicon oxide, silicon nitride and mixtures thereof.

In this embodiment of the present invention, as illustrated in FIG. 1c, the dielectric material 15 completely fills the regions 13a-13c. Furthermore, the dielectric material 15 in this embodiment does not only completely fill the regions 13a-13d but is also provided over the semiconductor layer 5 up to a thickness D. The thickness D can be determined by any known techniques such as optical ellipsometry and the likes. According to the present embodiment, the thickness D is substantially equal to at least the depth of a pit shown in FIG. 1c to at least recover the level of the surface 13 of the semiconductor layer 5.

FIG. 1d illustrates a step of polishing surface 17 of the dielectric material 15. The dielectric material 15 is polished using any conventional techniques such as chemical mechanical polishing (CMP). The dielectric material 15 is polished such that excess dielectric material over the semiconductor layer 5 is removed and the regions 13a-13d remain filled by remaining dielectric materials 15′. The surface of the semiconductor device structure 1 is polished such that the surface comprises regions free of defects and/or dislocations 11a-11d and free of excess dielectric material.

The excess dielectric material relates to those portions of the dielectric material, which are deposited on the exposed surface 13 but are not occluding surface openings of the pits. The excess dielectric material is removed during the polishing step. A surface smoothing process can also be performed on the exposed surface 13. The final roughness of the surface 13 after polishing steps before deposition of a metallic layer 7 is, for example, about a few nanometers for III-N material as GaN and less than 1 nm for Si, SiGe materials over a scan of 5×5 micrometers.

The semiconductor structure 1′, as illustrated in FIG. 1d, has fewer defects and/or dislocations when compared to the semiconductor structure 1, illustrated in FIG. 1a, due to the removal of defects and/or dislocations from the regions 13a-13d that extend through the semiconductor layer 5. Further, the semiconductor structure 1′ has an improved electrical quality due to passivation of the surface of the semiconductor layer 5 with the dielectric material 15.

FIG. 1e illustrates a step of providing a metallic layer 7 over the defect free semiconductor layer 5, thereby forming a semiconductor-metallic junction. Having the passivating pits, leakage currents in the interface region between the semiconductor layer and the metallic layer can be reduced and improved breakdown voltage characteristics, in particular in the vicinity of the interface, can be obtained.

According to the invention, the semiconductor structure comprises a Schottky barrier diode with the semiconductor layer 5 and the metallic layer 7 forming the semiconductor-metallic junction. Thus, with this Schottky diode, leakage currents can be reduced, thereby enabling a device with improved high electric field characteristics.

Preferably, the metallic layer (7) can be chosen from any one of Al, Au, Pt, chromium, palladium, tungsten, molybdenum or silicides from the same, for, e.g., SiPt2, and alloys or combinations thereof, and other metals having appropriate Schottky barriers and adhesion to semiconductor materials. The metallic layer can also be a polycrystalline or amorphous material. The metallic layer can be deposited, for example, by Physical vapor deposition (PVD), sputtering, Chemical vapor deposition (CVD) and the likes.

Preferably, the substrate 3 is removed or detached from the semiconductor layer 5 and be recycled if it does not present the right properties for subsequent application.

The individual features of the various embodiments can be combined independently of each other to reach further variations of the inventive embodiments.

The embodiments of the invention provide the advantage that an improved performance with respect to breakdown voltage can be observed when the defects and/or dislocations from the surface of the semiconductor layer are removed before the metallic layer is provided. Further, reduced leakage current can be observed in the vicinity of the interface between the metallic-semiconductor layer.

1. A method for fabricating a semiconductor structure comprising a semiconductor layer and a metallic layer, the method comprising the steps of:
a) providing a semiconductor layer comprising at least one of defects and dislocations
b) removing material at one or more locations of the at least one of defects and dislocations thereby forming pits in the semiconductor layer,
c) passivating the pits, and
d) providing the metallic layer over the semiconductor layer.

2. The method according to claim 1, wherein the passivating step c) includes a step of at least partially filing the pits with a dielectric material.

3. The method according to claim 2, wherein the material removal step b) comprises a step of etching the surface of the semiconductor layer preferentially at one or more locations of the at least one of defects and dislocations.

4. The method according to claim 2, wherein the dielectric material is selected from the group consisting of silicon oxide, silicon nitride and mixtures thereof.

5. The method according to claim 2, wherein the dielectric material completely fills the pits formed in step b).

6. The method according to claim 1, further comprising a step e) of polishing the surface of the semiconductor layer after step c) and before step d).

7. The method according to claim 1, wherein the metallic layer is provided by any one of physical vapor deposition (PVD), sputtering and chemical vapor deposition.

8. The method according to claim 7, wherein the semiconductor layer is selected from the group consisting of GaN, Silicon, strained Silicon, Germanium, SiGe, a III-V material, a III/N material, binary or ternary or quaternary alloy like GaN, InGaN, AlGaN, AlGaInN and the likes and wherein the metallic layer is Wiesen from any one of selected from the group consisting of Al, Au, Pt, chromium, palladium, tungsten, molybdenum, -silicides from the same, polycrystalline material and alloys, amorphous material and alloys, and combinations thereof.

9. A semiconductor structure, comprising a semiconductor layer and a metallic layer provided over the semiconductor layer, wherein pits at least partially filed with a dielectric material are arranged in the semiconductor layer on top of at least one of dislocations and defects in the semiconductor layer.

10. The semiconductor structure according to claim 9, wherein the metallic layer is provided on the semiconductor layer, and the pits extend up to the interface with the metallic layer.

11. The semiconductor structure according to claim 9, wherein the dielectric material is selected from the group consisting of silicon oxide, silicon nitride and mixtures thereof.

12. The semiconductor structure according to claim 9, wherein the pits are completely filed with the dielectric material.

13. (canceled)

14. A device using the semiconductor structure of claim 9.

15. The method according to claim 1, wherein the material removal step b) comprises a step of etching the surface of the semiconductor layer preferentially at one or more locations of the at least one of defects and dislocations.

16. The method according to claim 3, wherein the dielectric material is selected from the group consisting of silicon oxide, silicon nitride and mixtures thereof.

17. The method according to claim 3, wherein the dielectric material completely fills the pits formed in step b).

18. The method according to claim 3, further comprising a step e) of polishing the surface of the semiconductor layer after step c) and before step d).

19. The method according to claim 3, wherein the metallic layer is provided by any one of physical vapor deposition (PVD), sputtering and chemical vapor deposition.

20. The semiconductor structure according to claim 10, wherein the dielectric material is selected from the group consisting of silicon oxide, silicon nitride and mixtures thereof.

21. The semiconductor structure according to claim 10, wherein the pits are completely filed with the dielectric material.
